(19) United States
(12) Patent Application Publication
(10) Pub. No.: US 2010/0165726 A1
(43) Pub. Date: Jul. 1, 2010

(54) DISCHARGE PHASE CHANGE MATERIAL MEMORY

(76) Inventor: Daniel R. Shepard, North Hampton, NH (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/650,676

(22) Filed: Dec. 31, 2009

Related U.S. Application Data
(60) Provisional application No. 61/204,074, filed on Dec. 31, 2008.

(51) Int. Cl. G11C 11/00; G11C 7/00

(52) U.S. Cl. 365/163; 365/203; 365/148

(57) ABSTRACT

An information storage array includes a programmable material at a storage location and a capacitor set. A switching network charges the capacitor set to a first voltage and discharges the capacitor set at a second voltage. The second voltage is greater than the first voltage and it or a waveform derived therefrom is applied to the storage location to thereby change a state of the programmable material.

### CROSS-REFERENCE TO RELATED APPLICATIONS

This application claims priority to and the benefit of, and incorporates herein by reference in its entirety, U.S. Provisional Patent Application No. 61/204,074, which was filed on Dec. 31, 2008.

### TECHNICAL FIELD

In various embodiments, the present invention relates to the design and operation of solid-state memory arrays, and more particularly to the design and operation of memory arrays incorporating phase-change or resistive-change materials.

### BACKGROUND

Many types of non-volatile memory-storage cells exist in the prior art, including trapped-charge devices (e.g., flash memory) and altered-resistivity devices such as phase-change random-access memory (PRAM), resistive random-access memory (RRAM), or chalcogenide-based memories. Flash memory is relatively fast but suffers from short data-retention times. While phase-change materials generally retain data for longer times and have access times comparable to those of flash memories, process integration of phase-change materials may challenging due to their inability to withstand elevated thermal budgets.

Different forms of RRAM utilize different dielectric materials, spanning from perovskites to transition metal oxides to chalcogenides. An RRAM device typically features a conduction path (e.g., a filament or other path formed by application of a high voltage) through a dielectric, which is normally insulating. The conduction path may be broken (resulting in high resistance) and re-formed (resulting in low resistance) by appropriately applied voltages. By incorporating a resistive-change material in the memory cell, one alters the resistivity of the current path through the storage cell, thereby changing the state of the stored bit or bits. For examples of such resistive-change materials, see, e.g., U.S. Pat. Nos. 6,531,371, 6,867,996, 6,870,755, 6,946,702, 7,067,865, 7,157,750, and 7,292,469, the entire disclosure of each of which is incorporated by reference.

PRAM devices incorporate phase-change materials (PCMs) such as alloys of germanium, antimony, and tellurium (GST or, typically, Ge₂Sb₂Te₅). Exemplary devices incorporating GST are disclosed in, e.g., U.S. Pat. Nos. 3,983,542, 4,646,266, and 5,414,271, the entire disclosure of each of which is incorporated by reference. GST may be placed into its crystalline phase via application of a current through the cell sufficient to heat the GST followed by a slow diminishment of the current and associated heat. The slow cooling of the GST permits the atoms of the GST to align themselves into a crystalline phase. In order to place the GST into its amorphous state, the current is cut off abruptly. The resulting rapid cooling traps the GST atoms into the amorphous phase because they lack sufficient time to rearrange properly. Intermediate phases may be achieved by current reduction and associated cooling at rates between the two above-described points.

Any type of non-volatile memory will typically require elevated voltages for writing and/or erasing the cell contents. In order to provide this elevated voltage, a large portion of the die area is often dedicated to a voltage multiplier or charge pump having its own circuitry, as well as associated timing and oscillator circuits. In addition to consuming large die areas, these voltage pump circuits may be slow to “wake up” following reset, power-up, or being in sleep mode.

### SUMMARY

In various embodiments, the present invention includes a system and method for generating a high-current-density signal, suitable for writing or erasing a PCM material, with a small and fast voltage generation circuit. This circuit provides the required high current densities for writes to PCM memory cells. Memory devices fabricated in accordance with embodiments of the present invention feature memory cells including PCM or resistive-change materials, as well as a simplified voltage step-up circuit for writing and/or erasing the memory cell. The step-up circuit operates rapidly and obviates the need for large and complex support circuitry.

In general, in a first aspect, embodiments of the invention include an information storage array that includes a programmable material at a storage location, a capacitor set, and a switching network. The switching network charges the capacitor set to a first voltage and discharges the capacitor set at a second voltage greater than the first voltage. The second voltage, or a waveform derived therefrom, is applied to the storage location to thereby change a state of the programmable material.

The programmable material may include a phase-change material, a dielectric material, a perovskite, and/or a transition metal oxide; the phase change material may include a chalcogenide alloy, germanium, antimony, and/or telluride. Changing a state of the programmable material may include at least one of writing or erasing the programmable material. Applying the second voltage to the storage location may include passing a current through the programmable material. The capacitor set may include two or more capacitors switched together to form a desired capacitance, and in one embodiment, includes three capacitors. The first voltage may be a power supply voltage, and the second voltage may be three times the first voltage. A second capacitor set may be configured to charge while the other capacitor set, described above, is discharging.

In general, in another aspect, embodiments of the invention include a method for changing a state of a programmable material at a storage location in an information storage array. The method begins with charging a capacitor set to a first voltage by a switching network. The switching network generates a second voltage, greater than the first voltage, from the capacitor set. The second voltage and/or a waveform derived therefrom is applied to the storage location to thereby change a state of the programmable material.

The derived waveform may be one of a current waveform or a voltage waveform. Changing the state of the programmable material may include writing and/or erasing the programmable material. Applying the second voltage to the storage location may cause a current to be passed through the programmable material. The capacitor set may include two capacitors and the switching network, in applying the first voltage, may connect the two capacitors in parallel. The switching network may connect the two capacitors in series to generate the second voltage. The derived waveform may be one of a pulse waveform or a ramp waveform.

In general, in another aspect, embodiments of the invention include an information storage device that includes a programmable material at a storage location, a capacitor set, and a switching network. The switching network charges the capacitor set to a first voltage and discharges the capacitor set at a second voltage greater than the first voltage. The second voltage and/or a waveform derived therefrom is applied to the storage location to thereby change a state of the programmable material. The information storage device may be a compact flash memory, secure digital memory, multimedia card, PCMCIA card, and/or memory stick.

### BRIEF DESCRIPTION OF THE DRAWINGS

In the following description, various embodiments of the present invention are described with reference to the following drawings, in which:

FIG. 1 is a schematic diagram of a capacitor-switching circuit for writing and erasing a memory cell in accordance with various embodiments of the present invention; and

FIG. 2 is a flowchart of a method for writing and/or erasing a programmable material.

### DETAILED DESCRIPTION

Embodiments of the present invention address the high currents required for writing and/or erasing non-volatile memories (e.g., PRAM or RRAM) via generation and storage of a large-voltage charge. In various embodiments, the magnitude and duration of such currents are related to the memory cell geometry. For example, for a roughly 90 nm-geometry storage element incorporating Ge₂Sb₂Te₅ GST material, writing a memory bit may be accomplished by a 10 ns current pulse of approximately 500 μA; erasing the bit may be accomplished by a current pulse of approximately 300 ns that is approximately linearly ramped from approximately 500 μA to approximately 200 μA. While specific geometries and other related parameters are described herein in exemplary embodiments, embodiments of the present invention may be utilized more broadly in a wide range of non-volatile memory devices. While PCM materials are described herein, the present invention may be used with materials other than PCM.

At many (particularly larger) device geometries, the write and/or erase current for non-volatile memory cells is mainly a function of the memory cell itself. That is, the geometry and information-storage material of the cell effectively dictate the required currents and/or voltages for reading, writing, and erasing information, and the resistance of the access lines (e.g., the rows and columns of the array) is effectively negligible. However, as device geometries shrink, the resistance of the lines becomes more appreciable, and the voltage drop along the lines may even be a significant portion of the supply voltage. Thus, in various embodiments of the present invention, the current necessary to write and/or erase a memory cell is a function of the location of the cell. In such embodiments, a maximum required current may be calculated based on the longest path length to reach any of the memory cells in the array. The maximum current may then be utilized for the writing and/or erasing of each of the cells in the array.

In other embodiments, other memory-cell access techniques are utilized that maintain a constant access-path length through the array for each cell, thus maintaining the impedance (i.e., resistance) for cell access approximately constant for each cell. This impedance may be utilized (along with the required switching currents for the cell itself) to determine the current required to write and/or erase the cells in the memory array. Appropriate access techniques are described in U.S. Patent Application Publication No. 2009/0219741, the entire disclosure of which is incorporated by reference herein.

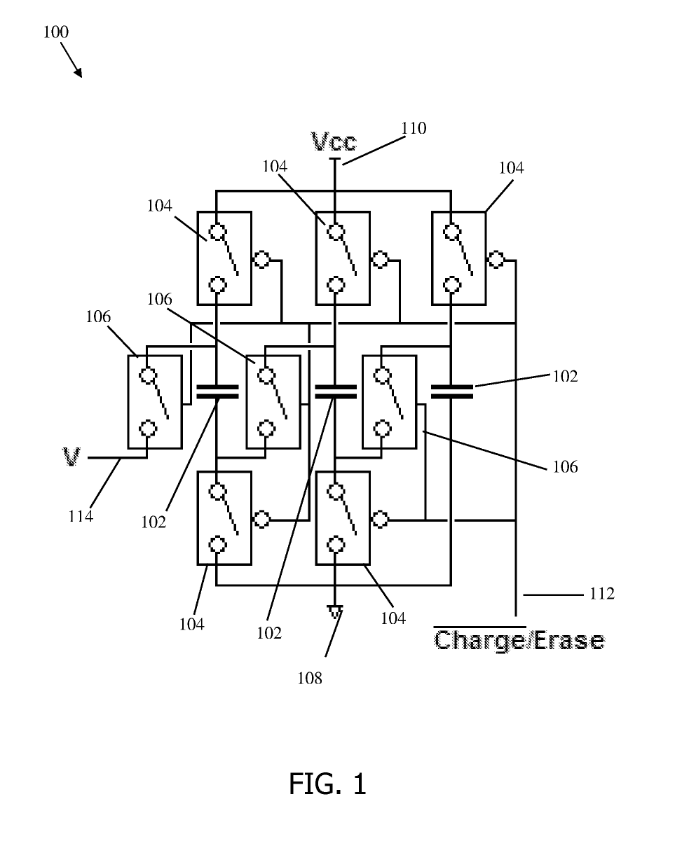

FIG. 1 is a schematic diagram of a switching circuit 100 for using a first, lower voltage to generate a second, higher voltage, in accordance with embodiments of the present invention. One or more capacitors 102 are controlled by a number of switches 104, 106. The switches 104, 106 may be solid-state devices, such as transistors or pass gates. A first set of switches 104 may be enabled and a second set of switches 106 may be disabled such that each of the capacitors 102 is connected, in parallel, between ground 108 and a positive supply voltage 110, thereby charging the capacitors 102 to the supply voltage 110. The switches 104, 106 may be enabled or disabled by a charge/erase signal 112. The capacitors 102 may be kept fully charged to the supply voltage 110 during a charging phase such as a stand-by mode or sleep mode. In one embodiment, upon power-up, the capacitors 102 are quickly charged by being switched to a low-impedance positive supply. When a bit is to be erased, the assertion of the control signal 112 is changed to disable the first set of switches 104 and to enable the second set of switches 106. In this discharge mode, the capacitors 102 are switched off from the positive supply 110 and into a series configuration. In this embodiment, the voltage stored on each of the capacitors 102 is added together, producing an output voltage at the output node 114 three times greater than the supply voltage 110. The output voltage may provide a maximum available voltage, which may be used to generate an output current or voltage waveform of equal or lesser value. The current invention is not limited to three capacitors 102, as shown, and may be practiced with any number of capacitors 102.

In general, the capacitors 102, the supply voltage 110, and/or the charge/erase signal 112 may be configured to provide a current and/or voltage waveform at the output node 114 necessary to write or erase a storage location in a non-volatile memory connected thereto. A given memory may require, for example, a 300-ns-long current pulse, ramped from 500 μA to 200 μA, to write a memory bit (as described above). The maximum current or voltage available is determined by the size and number of the capacitors 102, the resistance of the discharge path, and the potential of the power supply 110. Once the capacitors 102 are charged to their maximum value, they may be used to provide a current or voltage waveform of equal or lesser value. In discharge mode, the shape of the discharging current or voltage waveform is determined in part by the size of the capacitors 102, the resistance of the memory array and switching network 100, and/or the duration of the assertion of the charge/erase signal 112. Generating different waveforms from the elevated output voltage at the output node 114 (as may be required for writing or erasing) may easily be accomplished. For example, a current pulse may be provided by a brief (e.g., 10 ns) assertion of the charge/erase signal 112, while a current ramp may be provided by a long (e.g., 300 ns) assertion of the charge/erase signal 112. The slope of the output waveform ramp is determined in part by the RC time constant formed by the capacitors 102 and the resistance of the memory array.

In one illustrative example, the supply voltage 110 is ⅓ V, and each capacitor 102 is therefore charged to 1⅓ V in the charging phase. During the discharge phase, when the capacitors 102 are connected in series, the initial voltage on the output node is 3×1⅓ A V, or 4 V. To calculate the writing/erasing current produced by this voltage, some exemplary information about the memory array is presented. The scope of the present invention, however, is not limited to any particular configuration of memory array, and the size and number of the capacitors 102 may be modified to accommodate different types of memories, as required.

In this example, the memory array sized 8192 rows by 8192 columns. The memory devices are made with a geometry in which the minimum features are approximately 90 nm and the rows and spaces are at that minimum feature size. The resistance of a path through/across the memory, therefore, will be approximately a 4 KΩ for a row and 4 KΩ for a column for tungsten conductors of a particular thickness. These values, however, may be controlled within a range as is well-known and understood by those skilled in the art of semiconductor device manufacture. Assuming a conductor geometry and material for the rows and columns that yields a combined row and column path having 8 KΩ resistance, a capacitance value may be calculated that delivers a desired erase current waveform (i.e., a 300 ns current pulse that is linearly ramped from an initial 500 μA to a terminal 200 μA). The voltages required to provide the initial and terminal currents (computed using the formula V=IR) are 4.0 V (i.e., 8 KΩ×500 μA) and 1.6 V (i.e., 8 KΩ×200 μA), respectively. The change in voltage dV, therefore, is 2.4 V (i.e., 4.0 V−1.6 V) over the time interval (dT) of 300 ns. Thus, dV/dT is 2.4 V/300 nSec=8,000,000 V/sec. Because I=C dV/dT, noting that the initial voltage of 4.0 V corresponds to the initial current of 500 μA, the total required capacitance value is 62.5 fF. The capacitance of each capacitor 102, therefore, is 187.5 fF (because they are series-connected in discharge mode). In one embodiment, the resistance of the PCM element is incorporated in a more exact calculation if its value is significant compared to the path resistance.

Applying the 4 V generated voltage of FIG. 1 to the above-described exemplary memory array, once the discharge phase begins, the initial voltage creates the initial current (i.e., 500 μA) to begin the erase cycle. After 300 ns into the discharge phase, the capacitors 102 discharge by 2.4 V to a voltage level of 1.6 V, which corresponds to a current of 200 μA (i.e., the terminal current), at which point the current is quenched. Reducing the current in such a controlled manner will cause the PCM to solidify and anneal into a low-resistive crystalline state. Quenching may be achieved by deselecting the selected row and column, thereby disrupting the path through the array or by switching the series capacitor off from the array. To write the array, the operation is the same except that the quenching of the current occurs sooner (after, e.g., approximately 10 ns), causing the PCM to solidify in a high-resistive, amorphous state. Other voltages may be obtained with alternate supply voltage sources and different numbers of capacitors 102 (the above three-capacitor embodiment describes a tripler of the supply voltage). Other generated voltages may be used to provide a different initial current for erase as compared to write.

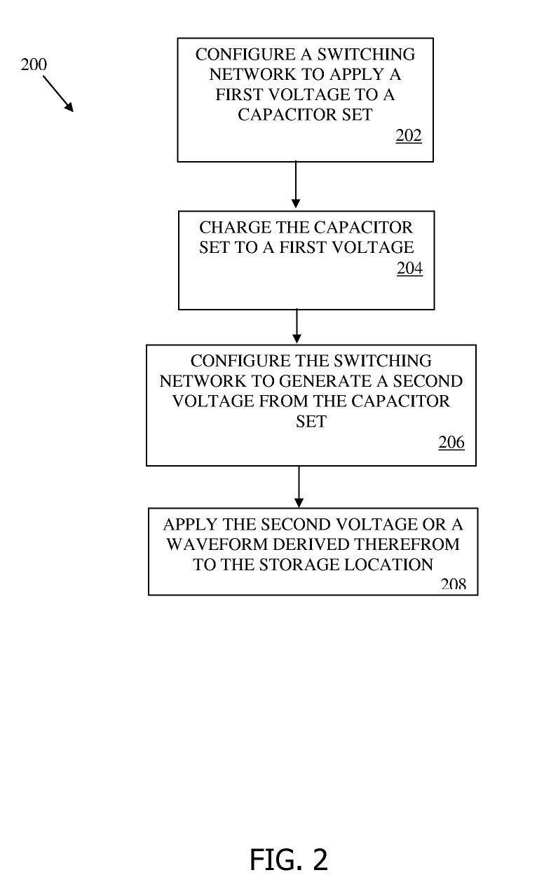

FIG. 2 is a flowchart illustrating, in one embodiment, a method for writing and/or erasing a programmable material. A switching network 104, 106 is configured to apply a first voltage 110 to a capacitor set 102 (Step 202). The capacitor set 102 is charged to the first voltage 110 (Step 204). The switching network 104, 106 is configured to generate a second voltage from the capacitor set 102 (Step 206). The second voltage is applied to a memory storage location to thereby change the state of a programmable material (Step 208). The second voltage is greater than the first voltage.

In one embodiment, two or more sets of capacitors 102 are incorporated into the memory array such that, while one set is switched in series onto the array to erase (i.e., in a discharge mode), another set is switched across the positive supply voltage (in, e.g., a charging mode). In one embodiment, this simultaneous charging and discharging of different sets of capacitors 102 will enable one set of capacitors 102 to always be charged and ready to erase the next bit in the array.

Writing the storage cell in a memory array is accomplished by heating the GST in the cell. This heating may be done by passing a current through the cell or by passing a current near enough to the cell to heat it. A bulk erase may be performed by heating the array or a portion of the array, thereby erasing multiple bits concurrently. Heating successive areas of the array may enable lower peak power consumption by starting the erase of groups of bits in succession (overlapping the heating of some bits while not necessarily starting and stopping the heating simultaneously, although this too could be done). Heating the memory device in a heating chamber may erase the entire array at once. The storage cell may be connected at a point of overlap of a row line or a bit line and a column line or a word line of a memory array such as a diode matrix memory array (with the anode to the row or bit line and the cathode to the column or word line or vice versa).

The present invention may find applicability in memory devices comprising an array of multiple sub-arrays, one or more of which may be accessed simultaneously. More bits of information may be read or written simultaneously to increase throughput or fewer bits of information may be read or written simultaneously to conserving power. Each sub-component/sub-array to be written or erased may have its own capacitor set 100 according to embodiments of the present invention. In one embodiment, a single capacitor set 100 is shared by more than one sub-component. Embodiments of the present invention may be used in memory devices comprising an array of multiple sub-arrays wherein the memory device is tiled into many sub-arrays for other purposes.

Embodiments of the present invention may be utilized in memory devices used in systems for storing digital text, digital books, digital music, digital audio, digital photography (wherein one or more digital still images is stored, including sequences of digital images), digital video, digital cartography (wherein one or more digital maps is stored), and any other digital or digitized information as well as any combinations thereof. These memory devices may be embedded, removable, or removable and interchangeable among other devices that access the data therein. They may be packaged in any variety of industry-standard form factors such as compact flash, secure digital, multimedia cards, PCMCIA cards, memory stick, and/or any of a large variety of integrated circuit packages including ball grid arrays, dual in-line packages (DIPs), SOICs, PLCCs, TQFPs, and the like, as well as in proprietary form factors and custom-designed packages. These packages may contain a single memory chip, multiple memory chips, or one or more memory chips along with other logic devices or other storage devices such as PLDs, PLAs, micro-controllers, microprocessors, memory controller chips or chip-sets, or other custom or standard circuitry. Packaging may include a connector for making electrical contact with another device when the device is removable or removable and interchangeable.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. An information storage array comprising:
a programmable material at a storage location;
a capacitor set; and
a switching network for charging the capacitor set to a first voltage and discharging the capacitor set at a second voltage, one of the second voltage or a waveform derived therefrom being applied to the storage location to thereby change a state of the programmable material,
wherein the second voltage is greater than the first voltage.

2. The storage array of claim 1, wherein changing a state of the programmable material comprises at least one of writing or erasing the programmable material.

3. The storage array of claim 1, wherein the programmable material comprises at least one of a phase-change material, a dielectric material, a perovskite, or a transition metal oxide.

4. The storage array of claim 1, wherein applying the second voltage to the storage location comprises passing a current through the programmable material.

5. The storage array of claim 2, wherein the phase change material comprises at least one of a chalcogenide alloy, germanium, antimony, or telluride.

6. The storage array of claim 1, wherein the capacitor set comprises two or more capacitors switched together to form a desired capacitance.

7. The storage array of claim 1, wherein the capacitor set comprises three capacitors.

8. The storage array of claim 1, wherein the first voltage is a power supply voltage.

9. The storage array of claim 1, wherein the second voltage is three times the first voltage.

10. The storage array of claim 1, further comprising a second capacitor set configured to charge while the other capacitor set is discharging.

11. A method for changing a state of a programmable material at a storage location in an information storage array, the method comprising:
charging a capacitor set to a first voltage by a switching network;
generating, by the switching network, a second voltage from the capacitor set, the second voltage being greater than the first voltage; and
applying one of the second voltage or a waveform derived therefrom to the storage location to thereby change a state of the programmable material.

12. The method of claim 11, wherein the derived waveform is one of a current waveform or a voltage waveform.

13. The method of claim 11, wherein changing the state of the programmable material comprises at least one of writing or erasing the programmable material.

14. The method of claim 11, wherein applying the second voltage to the storage location causes a current to be passed through the programmable material.

15. The method of claim 11, wherein the capacitor set comprises two capacitors.

16. The method of claim 15, wherein the switching network, in applying the first voltage, connects the two capacitors in parallel.

17. The method of claim 15, wherein configuring the switching network to generate the second voltage comprises connecting the two capacitors in series.

18. The method of claim 11, wherein the derived waveform is one of a pulse waveform or a ramp waveform.

19. An information storage device comprising:
a programmable material at a storage location;
a capacitor set; and
a switching network for charging the capacitor set to a first voltage and discharging the capacitor set at a second voltage, one of the second voltage or a waveform derived therefrom being applied to the storage location to thereby change a state of the programmable material,
wherein the second voltage is greater than the first voltage.

20. The information storage device of claim 19, wherein the information storage device is one of a compact flash memory, secure digital memory, multimedia card, PCMCIA card, or memory stick.
